(19) United States
(12) Patent Application Publication
(10) Pub. No.: US 2026/0248001 A1
(43) Pub. Date: Aug. 20, 2026

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Jae Min Bae, Seoul (KR); Hun Jung Lim, Sejong (KR); Jong Min Bark, Incheon (KR); Young Ho Oh, Incheon (KR)

(73) Assignee: Amkor Technology Singapore Holding Pte. Ltd., Singapore (SG)

(21) Appl. No.: 19/055,358

(22) Filed: Feb. 17, 2025

(51) Int. Cl. H01L 23/538; H01L 23/31; H01L 23/498; H01L 23/60

(52) U.S. Cl. CPC H10W 70/65; H10W 42/60; H10W 70/611; H10W 74/117; H10W 74/129; H10W 90/701

(57) ABSTRACT

In one example, an electronic device comprises a substrate comprising a first side, a second side opposite to the first side, a dielectric structure, and a conductive structure, a first electronic component coupled to the first side of the substrate and coupled to the conductive structure, a second electronic component coupled to the second side of the substrate and coupled to the conductive structure, a first encapsulant on the first side of the substrate and covering the first electronic component, a second encapsulant on the second side of the substrate and covering the second electronic component, a first interconnect structure in the second encapsulant and coupled to the conductive structure, and an external interconnect coupled to the first interconnect structure, wherein the external interconnect is external to the second encapsulant. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2I show cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. Unless specified otherwise, the term “coupled” may refer to a mechanical or electrical coupling.

### DESCRIPTION

In one example, an electronic device comprises a substrate comprising a first side, a second side opposite to the first side, a dielectric structure, and a conductive structure, a first electronic component coupled to the first side of the substrate and coupled to the conductive structure, a second electronic component coupled to the second side of the substrate and coupled to the conductive structure, a first encapsulant on the first side of the substrate and covering the first electronic component, a second encapsulant on the second side of the substrate and covering the second electronic component, a first interconnect structure in the second encapsulant and coupled to the conductive structure, and an external interconnect coupled to the first interconnect structure, wherein the external interconnect is external to the second encapsulant.

In another example, a method to manufacture an electronic device comprises providing a substrate comprising a first side, a second side opposite to the first side, a dielectric structure, and a conductive structure, providing a first electronic component coupled to the first side of the substrate and coupled to the conductive structure, providing a first encapsulant on the first side of the substrate and covering the first electronic component, providing a second electronic component coupled to the second side of the substrate and coupled to the conductive structure, providing a first interconnect structure coupled to the conductive structure, providing a second encapsulant on the second side of the substrate and covering the second electronic component and covering the first interconnect structure, and providing an external interconnect coupled to the first interconnect structure, wherein the external interconnect is external to the second encapsulant.

In yet another example, an electronic device comprises a substrate comprising a dielectric structure, and a conductive structure, an electronic component coupled to the substrate and coupled to the conductive structure, an interconnect structure coupled to the conductive structure, an encapsulant on the substrate and covering the electronic component and the interconnect structure, and an external interconnect coupled to the interconnect structure. The encapsulant includes a recessed region at an external side of the encapsulant, the interconnect structure extends into the recessed region, and the external interconnect extends into the recessed region and contacts a lateral side of the interconnect structure in the recessed region.

Other examples are included in the present disclosure. Such examples may be found in the figures, in the claims, or in the description of the present disclosure.

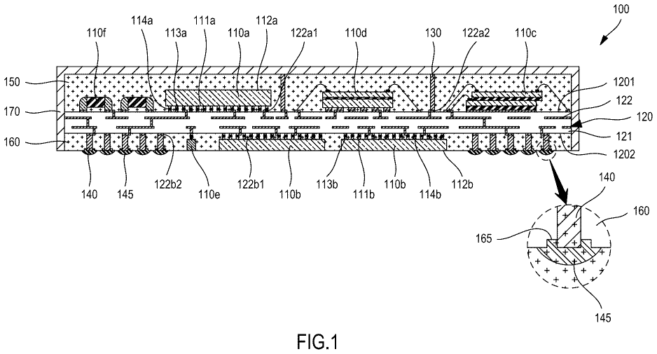

FIG. 1 shows a cross-sectional view of an example electronic device 100. In the example shown in FIG. 1, electronic device 100 can comprise electronic component 110a, electronic component 110b, electronic component 110c, electronic component 110d, electronic component 110e, or electronic component 110f, substrate 120, upper interconnect structure 130, lower interconnect structure 140, first encapsulant 150, second encapsulant 160, and shielding structure 170.

Electronic component 110a and electronic component 110b can each comprise first side 111a and first side 111b, which is an active side, and second side 112a and second side 112b, which is an inactive side. Electronic component 110a and electronic component 110b can comprise contact pad 113a and contact pad 113b. Electronic component 110a and electronic component 110b each can comprise connector 114a and connector 114b.

Substrate 120 can comprise first side 1201, second side 1202, dielectric structure 121, and conductive structure 122. Conductive structure 122 can comprise substrate inward terminal 122a1 and substrate inward terminal 122a2, substrate outward terminal 122b1, and substrate outward terminal 122b2.

Electronic component 110a and electronic component 110f can be electrically or mechanically connected to substrate inward terminals 122a1, respectively, through connectors 114a. Electronic component 110b and electronic component 110e can be electrically or mechanically connected to substrate outward terminals 122b1, respectively, through connectors 114b. Electronic component 110c and electronic component 110d can be electrically or mechanically connected to substrate inward terminals 122a1, respectively, through conductive wires.

Second interconnect structure 140 can comprise external interconnects 145. Second encapsulant 160 can comprise recessed region 165.

Substrate 120, upper interconnect structure 130, lower interconnect structure 140, first encapsulant 150, and second encapsulant 160 can be referred to as a semiconductor package, and the package can provide protection for electronic component 110a, electronic component 110b, electronic component 110c, electronic component 110d, electronic component 110e, or electronic component 110f from external elements or external exposure. The semiconductor package can provide electrical coupling between electronic components 110a, 110b, 110c, 110d, 110e, or 110f, and an external electronic component.

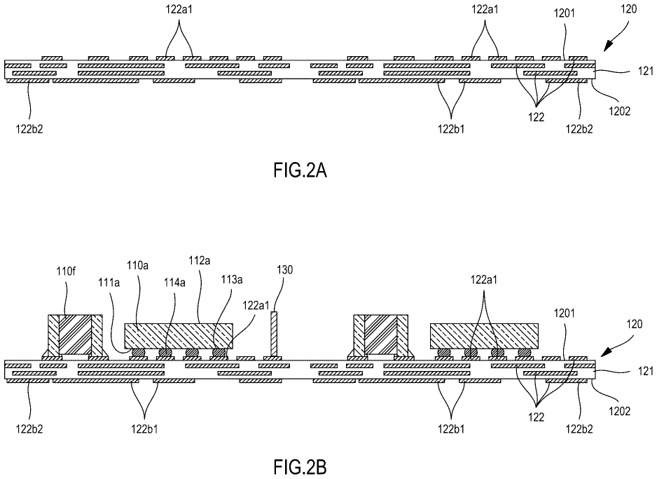

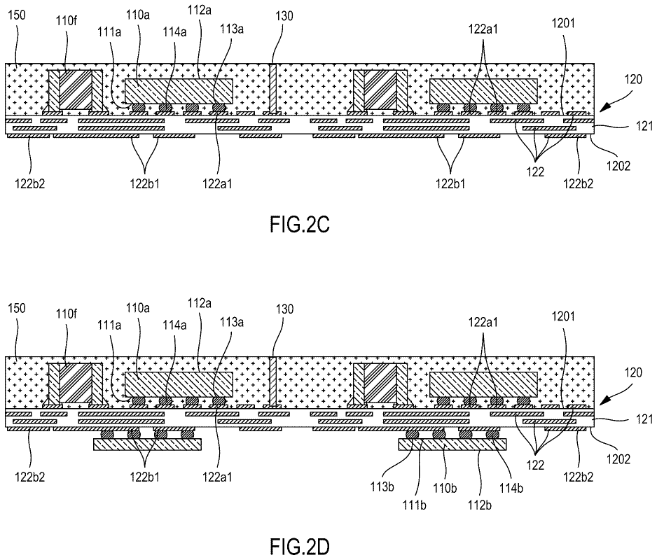

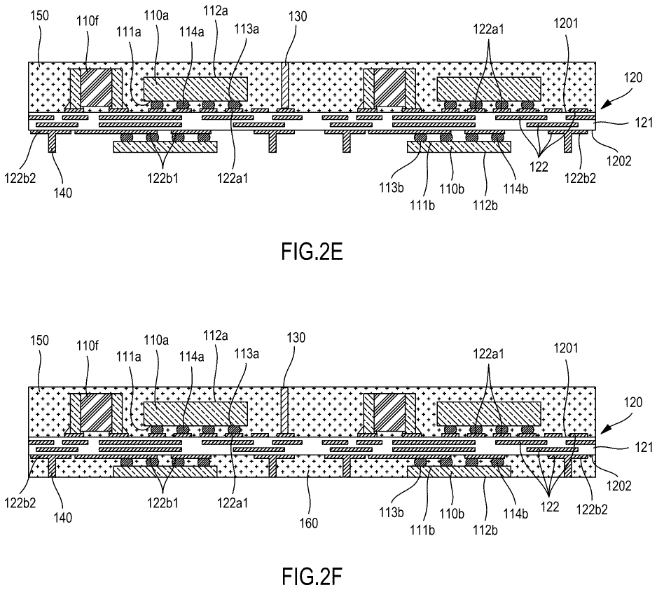

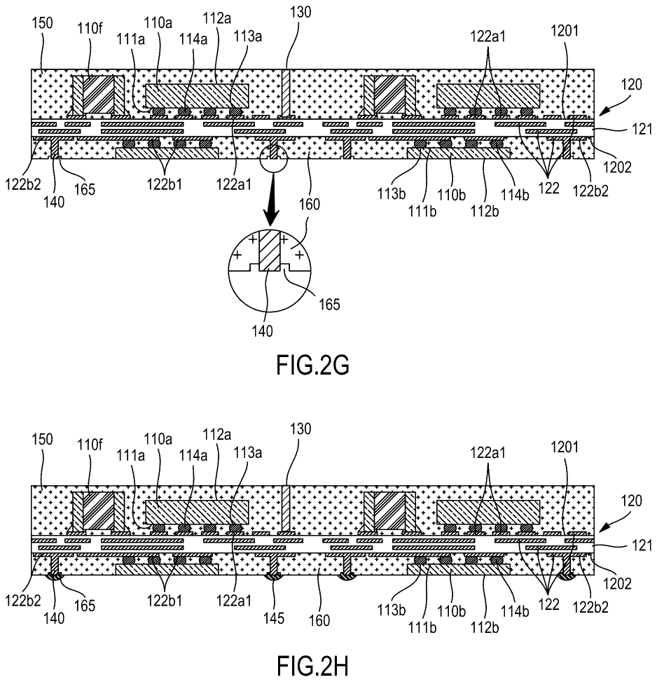

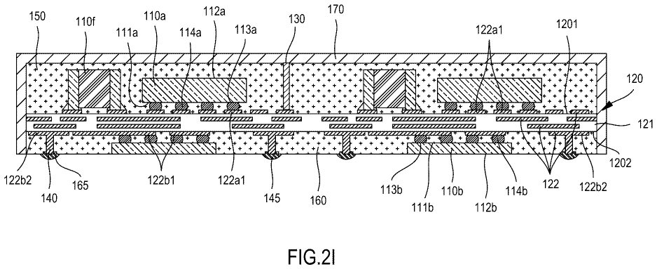

FIGS. 2A to 2I show cross-sectional views of an example method for manufacturing electronic device 100. FIG. 2A shows a cross-sectional view of electronic device 100 at an early stage of manufacture. In the example shown in FIG. 2A, substrate 120 can be provided.

Substrate 120 can comprise first side 1201, second side 1202 opposite to first side 1201, dielectric structure 121 between first side 1201 and second side 1202, and conductive structure 122 between first side 1201 and second side 1202. First side 1201 can be the upper side, or the lower side, of dielectric structure 121. Second side 1202 can be the lower side, or the upper side, of dielectric structure 121.

Dielectric structure 121 can comprise one or more layers of dielectric material interleaved between layers of conductive structure 122. Dielectric structure 121 can comprise or be referred to as a dielectric, an insulator, or a passivation. In some examples, dielectric structure 121 can comprise polyimide (PI), benzocyclobutene (BCB), polybenzoxazole (PBO), resin, an Ajinomoto buildup film (ABF), epoxy, or ceramic.

Conductive structure 122 can comprise one or more conductive layers defining signal or power distribution elements. The signal or power distribution elements can comprise or be referred to as traces, vias, pads, conductive paths, and under bumped metal (UBM). In some examples, conductive structure 122 can comprise copper, a copper alloy, aluminum, an aluminum alloy, gold, a gold alloy, silver, a silver alloy, nickel, a nickel alloy, palladium, a palladium alloy, or tin-silver.

Conductive structure 122 can be exposed through first side 1201 and can comprise substrate inward terminals 122a1 to which electronic component 110a and electronic component 110f are to later be electrically or mechanically connected. Substrate inward terminals 122a1 can comprise or be referred to as pads, lands, UBMs, or studs. Conductive structure 122 can be exposed through second side 1202 and can comprise substrate outward terminals 112b1 to which electronic components 110b are to later be electrically or mechanically connected. Conductive structure 122 can be exposed through second side 1202 and can comprise substrate outward terminals 112b2 to which lower interconnect structures 140 are to later be electrically or mechanically connected. Substrate outward terminals 122b1 and substrate outward terminal 122b2 can comprise or be referred to as two-step pads, pads, lands, UBMs, or studs.

In some examples, the exposed regions of substrate inward terminals 122a1 can be coplanar with first side 1201 of dielectric structure 121 or can form a different plane, such as a higher plane or a lower plane, than first side 1201. In some examples, the exposed regions of substrate outward terminal 122b1 and substrate outward terminal 122b2 can be coplanar with second side 1202 of dielectric structure 121 or can form a different plane, such as a higher plane or a lower plane, than second side 1202.

In some examples, the thickness of each of dielectric structure 121 and conductive structure 122 can range from approximately 1 μm to approximately 100 μm. In some examples, the overall thickness of substrate 120 can range from approximately 10 μm to approximately 2000 μm. In this way, substrate 120 comprising dielectric structure 121 and conductive structure 122 can be configured to support electronic component 110a or electronic component 110b while electrically or mechanically connecting electronic component 110a, electronic component 110b, or electronic component 110f to an external device.

In some examples, substrate 120 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

In some examples, substrate 120 can be a redistribution layer (“RDL”) substrate. RDL substrates can comprise one or more conductive redistribution layers and one or more dielectric layers that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), polybenzoxazole (PBO), resin or an Ajinomoto build-up film (ABF). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layers can comprise silicon nitride (Si3N4), silicon oxide (SiO2), or SiON. The inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate.

FIG. 2B shows a cross-sectional view of electronic device 100 at a later stage of manufacture. In the example shown in FIG. 2B, electronic component 110a or electronic component 110f can be mounted on substrate 120. In some examples, upper interconnect structure 130 can be mounted on substrate 120.

Electronic component 110a or electronic component 110f can be electrically or mechanically connected to conductive structure 122 exposed through first side 1201 of substrate 120. In some examples, electronic component 110a or electronic component 110f can be electrically or mechanically connected to substrate inward terminals 122a1. In some examples, upper interconnect structure 130 can be electrically or mechanically connected to substrate inward terminals 122a1.

Electronic components 110a can each comprise first side 111a, second side 112a opposite to first side 111a, contact pads 113a provided on first side 111a, and connectors 114a that electrically or mechanically connect contact pads 113a to substrate inward terminals 122a1.

In some examples, electronic component 110a or electronic component 110f can comprise or be referred to as dies, chips, packages, passive components, antenna patches, intelligent power devices (IPDs), or stacked dies. In some examples, electronic components 110a can comprise digital signal processors (DSPs), network processors, power management units, audio processors, radio-frequency (RF) circuits, wireless baseband processors, system-on-chip (SoC) processors, sensors, or application-specific integrated circuits. The thicknesses of electronic component 110a or electronic component 110f can range from approximately 20 μm to approximately 1000 μm. Electronic component 110a or electronic component 110f can perform calculation and control processing, store data, or remove noise from electrical signals.

First side 111a of each of electronic components 110a can comprise an active side closer to substrate 120, and second side 112a of each of electronic components 110a can comprise an inactive side farther from substrate 120. In some examples, first side 111a can comprise a lower side, and second side 112b can comprise an upper side.

In some examples, contact pads 113a can comprise or be referred to as bond pads exposed through an inorganic material, for example silicon dioxide (SiO2) or silicon nitride (Si3N4), or redistribution layer (RDL) pads exposed through a dielectric layer. In some examples, connectors 114a can comprise or be referred to as bumps, tin-lead (SnPb) bumps, lead-free bumps, copper pillars, stud bumps, pillars or posts. Connectors 114a can electrically or mechanically connect contact pads 113a of electronic component 110a or electronic component 110f to substrate inward terminals 122a1.

FIG. 2C shows a cross-sectional view of electronic device 100 at a later stage of manufacture. In the example shown in FIG. 2C, first encapsulant 150 can be provided.

First encapsulant 150 can cover electronic component 110a or electronic component 110f on substrate 120. First encapsulant 150 can cover first side 1201 of substrate 120 and electronic component 110a or electronic component 110f. First encapsulant 150 can be in contact with first side 1201 of substrate 120, electronic component 110a, or electronic component 110f. First encapsulant 150 can comprise or be referred to as an epoxy molding compound, a resin, a filler-reinforced polymer, a B-stage compression film, or a gel. In some examples, first encapsulant 150 can completely cover electronic component 110a or electronic component 110f so that electronic component 110a or electronic component 110f are not exposed to the outside. In some examples, second side 112a of electronic component 110a can be exposed to the outside through first encapsulant 150. The thickness of first encapsulant 150 can range from approximately 0.01 millimeter (mm) to approximately 10 mm. First encapsulant 150 can protect electronic component 110a or electronic component 110f from the external environment.

FIG. 2D shows a cross-sectional view of electronic device 100 at a later stage of manufacture. In the example shown in FIG. 2D, electronic components 110b can be mounted on substrate 120.

Electronic components 110b can be electrically or mechanically connected to conductive structure 122 exposed through second side 1202 of substrate 120. In some examples, electronic components 110b can be electrically or mechanically connected to substrate outward terminals 122b1. Electronic components 110b can each comprise first side 111b, second side 112b opposite to first side 111b, contact pads 113b provided on first side 111b, and connectors 114b that electrically or mechanically connect contact pads 113b to substrate outward terminals 122b1.

In some examples, electronic components 110b can comprise or be referred to as dies, chips, packages, passive components, antenna patches, intelligent power devices (IPDs), or stacked dies. In some examples, electronic components 110b can comprise digital signal processors (DSPs), network processors, power management units, audio processors, radio-frequency (RF) circuits, wireless baseband processors, system-on-chip (SoC) processors, sensors, or application-specific integrated circuits. The thicknesses of electronic components 110b can range from approximately 20 μm to approximately 1000 μm. Electronic components 110b can perform calculation and control processing, store data, or remove noise from electrical signals.

First side 111b of each of electronic components 110b can comprise an active side closer to substrate 120 and second side 112b of each of electronic components 110b can comprise an inactive side farther from substrate 120. In some examples, first side 111b can comprise an upper side, and second side 112b can comprise a lower side.

In some examples, contact pads 113b can comprise or be referred to as bond pads exposed through an inorganic material, for example silicon dioxide (SiO2) or silicon nitride (Si3N4), or redistribution layer (RDL) pads exposed through a dielectric layer. In some examples, connectors 114b can comprise or be referred to as bumps, SnPb bumps, lead-free bumps, copper pillars, stud bumps, pillars or posts. Connectors 114b can electrically or mechanically connect contact pads 113b of electronic components 110b to substrate outward terminals 122b1.

FIG. 2E shows a cross-sectional view of electronic device 100 at a later stage of manufacture. In the example shown in FIG. 2E, lower interconnect structures 140 can be mounted on substrate 120.

Lower interconnect structures 140 can be electrically or mechanically connected to conductive structure 122 of substrate 120. In some examples, lower interconnect structures 140 can be electrically or mechanically connected to substrate outward terminals 122b2 provided on second side 1202 of substrate 120. In some examples, lower interconnect structures 140 can comprise or be referred to as conductive wires, wire pillars, or wire posts.

In some examples, lower interconnect structures 140, or wire pillars, can be provided by using a wire bonding process, and an exemplary method thereof will now be described. First, wire bonding equipment is prepared. For example, thermo-ultrasonic wire bonding equipment can be prepared. The bonding equipment can provide precise position control, force, temperature, or ultrasonic vibration, which are involved for forming a wire pillar. The conductive wire can comprise a conductive metal such as gold (Au), copper (Cu), and silver (Ag), and a relatively thick metal wire can be used in a wire bonding process. The diameters of conductive wires can range from approximately 20 μm to approximately 100 μm. Next, substrate 120 having the aforementioned structure can be prepared. For example, substrate 120 having a plurality of substrate outward terminals 122b2 provided on second side 1202 can be provided. Subsequently, a wire bonding process can be performed. In some examples, a plurality of lower interconnect structures 140 can be provided on second side 1202 of substrate 120. In some examples, an array of lower interconnect structures 140 can be provided on second side 1202 of substrate 120. In some examples, adjacent lower interconnect structures 140 can be spaced apart at a distance or pitch of 75 micrometers (μm) or less, although the scope of the disclosed subject matter is not limited in this respect.

Providing a wire pillar is basically a process to which a wire bonding process is applied, and can be performed through the following steps. First, a ball bonding process can be performed. Small spherical metal balls can be provided at an end of a wire through an electronic flame off (EFO) process. In some examples, spherical balls can be formed by melting the end of the wire through an arc discharge when current flows through an electrode. The metal balls can be bonded to substrate outward terminals 122b2 on substrate 120 through heat, pressure, or ultrasonic waves. During this process, bonding can be firmly formed.

Subsequently, a wire elongation and cutting process can be performed. After the metal balls are bonded and connected to substrate outward terminals 122b2, the wire can be elongated in the vertical direction. Here, a bonding head can be raised and the wire can be raised along with the bonding head. Wire bonding equipment can stretch the wire to an appropriate height and then cut the wire. During this process, lower interconnect structures 140 in the form of wire pillars or wire posts can be provided.

The remaining portions of the cut wire become wire pillars vertically standing on or extending from substrate outward terminals 122b2. The bonding height and the thickness of the wire can be adjusted depending on the settings of the bonding equipment.

Finally, the height of lower interconnect structure 140 can range from approximately 100 μm to approximately 2000 μm. Lower interconnect structures 140 can mechanically or electrically connect electronic device 100 to an external device. Although having been described herein as being provided on second side 1202 of substrate 120, lower interconnect structures 140 can also be provided on first side 1201 of substrate 120 in a similar structure and manner.

FIG. 2F shows a cross-sectional view of electronic device 100 at a later stage of manufacture. In the example shown in FIG. 2F, second encapsulant 160 can be provided.

Second encapsulant 160 can cover electronic components 110b and lower interconnect structures 140 on substrate 120. In some examples, second encapsulant 160 can cover second side 1202, electronic components 110b, and lower interconnect structures 140 on substrate 120. Second encapsulant 160 can be in contact with second side 1202, electronic components 110b, and lower interconnect structures 140 of substrate 120. Second encapsulant 160 can comprise or be referred to as an epoxy molding compound, a resin, a filler-reinforced polymer, a B-stage compression film, or a gel. In some examples, second encapsulant 160 can completely cover electronic components 110b.

In some examples, second encapsulant 160 can be supplied by compression molding, transfer molding, liquid encapsulant molding, vacuum lamination, paste printing or film assisted molding methods. As an example, compression molding can be a process in which a fluidic resin is supplied into a mold in advance and electronic device 100 is then placed in the mold to cure the fluidic resin, and transfer molding can be a process in which a fluidic resin is supplied from a gate or supply port of a mold to the periphery of electronic device 100 and then cured. The thickness of second encapsulant 160 can range from approximately 100 μm to approximately 2000 μm. Second encapsulant 160 can protect electronic components 110b, lower interconnect structures 140, and substrate 120 from the external environment.

In some examples, a back-grinding process can be performed after the curing process of second encapsulant 160. In some examples, the grinding process of second encapsulant 160 can be performed after first encapsulant 150 is bonded to a carrier by a temporary adhesive. In some examples, the grinding process can include a coarse grinding process to rapidly reduce the thickness of second encapsulant 160 in an initial stage by using grinding equipment, and then a fine grinding process to more precisely and finely grind second encapsulant 160 to reduce surface roughness and reach a desired thickness. In some examples, a coolant or a cooling liquid can be used to dissipate the heat generated during the grinding process.

After the grinding process, the lower side, or second side 112b, of each of electronic components 110b and the lower side of each of lower interconnects 140 can be exposed to the outside through second encapsulant 160. In some examples, the lower side, or second side 112b, of each of electronic components 110b and the lower side of each of lower interconnects 140 can be coplanar with the lower side of second encapsulant 160.

FIG. 2G shows a cross-sectional view of electronic device 100 at a later stage of manufacture. In the example shown in FIG. 2G, recessed region 165 can be provided in second encapsulant 160. Recessed region 165 can be provided such that the lateral side connected to the lower surface of each of lower interconnect structures 140 is exposed.

Recessed region 165 can be provided by laser ablation, chemical etching, or mechanical processing. Laser ablation can include using a laser beam to locally remove a portion of second encapsulant 160 around lower interconnect structures 140. This can be done by focusing a high energy laser on the encapsulant to vaporize or burn the surface of the encapsulant, thereby forming fine recesses. Chemical etching can be a process in which a groove is formed by selectively dissolving a portion of second encapsulant 160 around lower interconnect structures 140 by using a chemical solution. This process can be a process in which a mask is applied to the surface of the encapsulant to expose only a desired pattern portion, and the exposed portion is then chemically etched and removed. Mechanical processing can be a process in which a groove is formed in a portion of the second encapsulant by using a physical tool. For example, a portion of the second encapsulant can be physically cut and removed by using a computer numerical control (CNC) milling machine or a diamond tool. The depth and width of recessed region 165 can range from approximately 10 μm to approximately 100 μm. Recessed region 165 can allow for external interconnects 145 to be stably connected to the lower interconnect structures 140 in the future, for example as shown in FIG. 2H. In some examples, external interconnects 145 can be referred to as a stud, and lower interconnect structures 140 can be referred to as a tail, although the scope of the disclosed subject matter is not limited in this respect.

FIG. 2H shows a cross-sectional view of electronic device 100 at a later stage of manufacture. In the example shown in FIG. 2H, external interconnects 145 can be provided. External interconnects 145 can comprise or be referred to as solder balls, bumps, pads, or pillars. External interconnects 145 can be electrically or mechanically connected to lower interconnect structures 140. External interconnects 145 can surround the lower and side surfaces of lower interconnect structures 140 within recessed region 165. In some examples, the lower side of each of external interconnects 145 can be lower than the lower side of second encapsulant 160.

In some examples, external interconnects 145 can be provided by a soldering process. For example, a flux can be applied to portions of lower interconnect structures 140 exposed and protruding through recessed region 165. The flux removes an oxide film between the solder and lower interconnect structures 140 to facilitate bonding. Subsequently, a solder face or solder ball can be precisely placed on the flux. In some examples, the solder can include a ton-lead (Sn—Pb) alloy or a lead-free solder (SnAgCu). After the solder is placed, the solder can be heated by a reflow process. Here, the solder can melt and bond with portions of lower interconnect structures 140 to form electrical or mechanical connection. The solder can fill recessed region 165 and surround the lower side of each of lower interconnect structures 140 and the lateral side connected to the lower side. The thickness of external interconnect 145 including solder can range from approximately 100 μm to approximately 500 μm. External interconnects 145 can serve to electrically connect electronic device 100 to an external device. In some examples, recessed region 165 can serve to expose more surface area of lower interconnect structure 140 to allow for solder to pool into recessed regions 165 and bond with a greater surface area of lower interconnect structure 140 than if recessed region 165 was not present, although the scope of the disclosed subject matter is not limited in this respect. In addition, plating operations such as an electroless nickel immersion gold (ENIG) process on the ends of lower interconnect structures 140 can be avoided or eliminated by providing recessed regions 165 to allow external interconnects 145 to have a greater bonding area and bonding strength with lower interconnect structures 140, although the scope of the disclosed subject matter is not limited in these respects.

FIG. 2I shows a cross-sectional view of electronic device 100 at a later stage of manufacture. In the example shown in FIG. 2I, shielding structure 170 can be provided. Shielding structure 170 can surround or cover the upper and lateral sides of first encapsulant 150. Shielding structure 170 can also surround or cover the lateral side of substrate 120. In some examples, shielding structure 170 can be in contact with dielectric structure 121 and can also be electrically or mechanically connected to conductive structure 122, for example a ground conductor of conductive structure 122. In some examples, shielding structure 170 can surround or cover the lateral side of second encapsulant 160. Shielding structure 170 can comprise or be referred to as an electromagnetic interference (EMI) shielding film. Shielding structure 170 can comprise aluminum, copper, nickel, gold, silver, or alloys, which have excellent conductivity and are effective in blocking EMI.

Shielding structure 170 can be provided through a sputtering process in which high-energy ions collide with a metal material in a vacuum chamber to deposit metal atoms on the surface of a package, a physical vapor deposition (PVD) process in which a metal is vaporized and deposited on the surface of a package, or a chemical vapor deposition (CVD) process in which a metal layer is deposited on the surface of a package by using a chemical reaction.

In addition, shielding structure 170 can be provided through a spray coating process in which a spray of fine particles of a conductive metal is applied to the surface of a package. For this purpose, either a solution having a metal chemically dispersed or a nanoparticle-based coating can be used. In addition, shielding structure 170 can be provided through a plasma spray process in which plasma is used to melt a metal at high temperature and spray the same onto the surface of a package. In addition, shielding structure 170 can be provided through a plating process in which a metal layer is formed on the surface of a package through an electrochemical reaction in an electrolyte solution. In addition, shielding structure 170 can be provided through a conductive paste coating process in which a conductive paste containing nano-sized metal particles is applied onto a package through screen printing, spin coating, and so on. The thickness of shielding structure 170 can range from approximately 1 μm to approximately 10 μm. Shielding structure 170 can serve to protect electronic device 100 from external electromagnetic waves. In addition, shielding structure 170 can serve to prevent electromagnetic waves from being radiated from electronic device 100 to the outside.

The present disclosure includes reference to certain examples. It will be understood by those skilled in the art, however, that various changes can be made and equivalents can be substituted without departing from the scope of the disclosure. In addition, modifications can be made to the disclosed examples without departing from the scope of the present disclosure. Therefore, it is intended that the present disclosure is not limited to the examples disclosed, but that the disclosure will include all examples falling within the scope of the appended claims.

1. An electronic device, comprising:
a substrate comprising a first side, a second side opposite to the first side, a dielectric structure, and a conductive structure;
a first electronic component coupled to the first side of the substrate and coupled to the conductive structure;
a second electronic component coupled to the second side of the substrate and coupled to the conductive structure;
a first encapsulant on the first side of the substrate and covering the first electronic component;
a second encapsulant on the second side of the substrate and covering the second electronic component;
a first interconnect structure in the second encapsulant and coupled to the conductive structure; and
an external interconnect coupled to the first interconnect structure, wherein the external interconnect is external to the second encapsulant.

2. The electronic device of claim 1, wherein the external interconnect contacts a lateral side of the first interconnect structure.

3. The electronic device of claim 1, wherein the second encapsulant has a recessed region, and the second encapsulant is spaced apart from the first interconnect structure at the recessed region.

4. The electronic device of claim 3, wherein the external interconnect extends into the recessed region.

5. The electronic device of claim 3, wherein the external interconnect covers the recessed region.

6. The electronic device of claim 1, wherein the external interconnect is between the first interconnect structure and the second encapsulant.

7. The electronic device of claim 1, wherein the first interconnect structure comprises a wire post.

8. The electronic device of claim 1, comprising a second interconnect structure in the second encapsulant and coupled to the conductive structure, wherein the second interconnect structure is spaced apart from the first interconnect structure at a distance of 75 micrometers or less.

9. The electronic device of claim 1, comprising a shielding structure covering the first encapsulant.

10. The electronic device of claim 9, wherein the shielding structure covers a lateral side of the first encapsulant.

11. The electronic device of claim 9, wherein the shielding structure covers a lateral side of the substrate.

12. The electronic device of claim 9, wherein the shielding structure covers a lateral side of the second encapsulant.

13. The electronic device of claim 9, comprising a second interconnect structure in the first encapsulant, wherein the second interconnect structure is coupled to the conductive structure and the shielding structure.

14. The electronic device of claim 9, wherein the first interconnect structure has a diameter of 100 micrometers or less.

15. A method to manufacture an electronic device, comprising:
providing a substrate comprising a first side, a second side opposite to the first side, a dielectric structure, and a conductive structure;
providing a first electronic component coupled to the first side of the substrate and coupled to the conductive structure;
providing a first encapsulant on the first side of the substrate and covering the first electronic component;
providing a second electronic component coupled to the second side of the substrate and coupled to the conductive structure;
providing a first interconnect structure coupled to the conductive structure;
providing a second encapsulant on the second side of the substrate and covering the second electronic component and covering the first interconnect structure; and
providing an external interconnect coupled to the first interconnect structure, wherein the external interconnect is external to the second encapsulant.

16. The method of claim 15, wherein the external interconnect contacts a lateral side of the first interconnect structure.

17. The method of claim 15, comprising providing a recessed region in the second encapsulant prior to providing the external interconnect, wherein the second encapsulant is spaced apart from the first interconnect structure at the recessed region.

18. The method of claim 17, wherein the external interconnect extends into the recessed region.

19. An electronic device, comprising:
a substrate comprising a dielectric structure, and a conductive structure;
an electronic component coupled to the substrate and coupled to the conductive structure;
an interconnect structure coupled to the conductive structure;
an encapsulant on the substrate and covering the electronic component and the interconnect structure; and
an external interconnect coupled to the interconnect structure;
wherein:
the encapsulant includes a recessed region at an external side of the encapsulant;
the interconnect structure extends into the recessed region; and
the external interconnect extends into the recessed region and contacts a lateral side of the interconnect structure in the recessed region.

20. The electronic device of claim 19, wherein:
the interconnect structure comprises a wire post; and
the external interconnect covers the recessed region and the external side of the encapsulant.
